(19) United States
(12) Patent Application Publication
(10) Pub. No.: US 2011/0026749 A1
(43) Pub. Date: Feb. 3, 2011

(54) FRAME FOR A PORTABLE ELECTRONIC DEVICE

(76) Inventor: Ronald A. Yaun, Macon, GA (US)

Correspondence Address: BRIAN D. BELLAMY, P.O. BOX 1997, THOMASVILLE, GA, 31799-1997, US

(21) Appl. No.: 12/846,631

(22) Filed: Jul. 29, 2010

Related U.S. Application Data
(60) Provisional application No. 61/229,557, filed on Jul. 29, 2009.

(51) Int. Cl. H04R 9/06; H05K 7/18

(52) U.S. Cl. 381/333; 361/829

(57) ABSTRACT

A frame for a portable electronic device comprising a frame body with stand or hanger attached to a receptacle for receiving the portable electronic device. The receptacle has a receiving slot for insertion of the portable electronic device, and the receptacle holds the digital display of the device in alignment with a display opening of the frame body. The portable electronic device is inserted directly into the receptacle or using a protective sleeve. The receptacle optionally includes an accessory opening or electronic module used for providing power to the portable electronic device or attaching other accessories. The frame provides a method of using a portable electronic device as a digital photo frame with an ornamental accent about the digital display provided by a front face member. When the portable electronic device is not in use, a printed photo insert is provided for display.

### PRIORITY CLAIM

The present application claims benefit of U.S. Provisional Application No. 61/229,557 filed on Jul. 29, 2009.

### BACKGROUND OF THE INVENTION

The present invention relates to digital photo frames and, in particular to a frame arranged to receive a portable electronic device capable of displaying photos.

Digital photo frames have been produced for several years, using a LCD display and a digital processor enclosed in a picture frame, usually constructed of wood or plastic. The digital photo frame comes in various sizes, styles and colors. The digital photo frame displays digital images stored in internal memory or some type of memory card inserted into the device. The digital images are transferred to the digital photo frame via memory cards or wireless networks. Many of the digital photo frames present the digital images as a slide show, providing the user with the ability to adjust certain features.

The digital photo frame has gained popularity in the past few years and has become a commercial success. The global market for digital photo frames is projected to grow at a compound annual growth rate of 25 percent until 2012. With increased production costs, plus the higher raw material and labor costs the price is expected to increase by 10 percent.

Typical digital photo frames, as described above, are shown, for example, in the following U.S. Pat. Nos. D560,371; D558,460. In these devices, an attractive frame is arranged around a built-in LCD screen having memory and integrated electronics for sequentially displaying digital photos.

The progress made in the portable electronic device (e.g., MP3 players, smart phones, personal digital assistants, etc.) and the functionality provided, makes it an ideal device to take the place of the LCD and processor in a digital photo frame. Using the portable electronic device for digital photo display may save the consumer the cost of purchasing a separate digital photo frame. A variety of stands and cradles have been designed to hold such electronic devices for charging or display. However, cradles and like stands are not aesthetically pleasing for display of photos and do not perform as a suitable digital photo frame. Thus, what is needed is a device for displaying photos on a portable electronic device that will resemble the pleasing appearance of a digital photo frame.

### SUMMARY OF THE INVENTION

The present invention provides a device for displaying photos using a portable electronic device housed within a frame. The frame provides a method of using a portable electronic device as a digital photo frame. The frame has a frame body that stands upright using a stand or hangs from a wall using a hanger means. A front face is outwardly displayed on a first surface of the frame body for providing a pleasing appearance. The front face may be integrally formed with the first surface of the frame body or provided as a detachable front face member that attached to the frame body. A receptacle affixed to the rear face of the frame body is configured for insertion of the portable electronic device through a receiving slot. The receptacle holds the digital display of the device in alignment with a display opening that is centrally framed by the frame body. The frame body is designed so that the digital display appears similar to the display of a digital photo frame. The portable electronic device is inserted directly into the receptacle or using a protective sleeve. The receptacle design or protective sleeve design may vary according to the preferred portable electronic device or variety of functions desired for the frame. For instance, the receptacle optionally includes an accessory opening or electronic module used for providing power to the portable electronic device or attaching other accessories, such as audio speakers. When the portable electronic device is not in use, a printed photo insert may be provided so as to provide an attractive decorative feature.

An object of the present invention is to provide an alternative to a digital photo frame. The present invention used a portable electronic device in combination with a frame for housing that device to provide such an alternative.

Another object of the present invention is to provide a frame for displaying digital photos from a portable electronic device while recharging that device.

Another object of the present invention is to provide a frame for displaying digital photos from a portable electronic device while also playing music from the portable electronic device or accessing additional media capabilities of the device including video.

And yet another object of the present invention is to provide a frame for displaying digital photos from a portable electronic device such as a cell phone and displaying a printed photo when the portable electronic device has been removed from the frame.

### BRIEF DESCRIPTION OF THE DRAWINGS

FIG. 1 is an assembled perspective view of a frame for receiving a portable electronic device according to an exemplary embodiment of the present invention.

FIG. 2 is an exploded front perspective view of a portable electronic device and a frame for receiving the portable electronic device according to an exemplary embodiment.

FIG. 3 is an exploded rear perspective view of a portable electronic device and a frame for receiving the portable electronic device according to an exemplary embodiment.

FIG. 4 is an assembled rear perspective view of a frame for receiving a portable electronic device according to an exemplary embodiment.

FIG. 5 is an exploded rear perspective view of a frame for receiving a portable electronic device according to an exemplary embodiment.

FIG. 6 is a front perspective view of a frame for receiving a portable electronic device according to an exemplary embodiment.

FIG. 7 is an exploded rear perspective view of a portable electronic device and a frame for receiving the portable electronic device and insert system according to an exemplary embodiment.

FIG. 8 is an exploded rear perspective view of a portable electronic device and a frame for receiving the portable electronic device and insert system according to an exemplary embodiment.

FIG. 9 is a front perspective view of a frame for receiving a portable electronic device according to an exemplary embodiment.

FIG. 10 is an exploded front perspective view of a frame for receiving a portable electronic device and a photo insert system according to an exemplary embodiment.

### DETAILED DESCRIPTION OF THE INVENTION

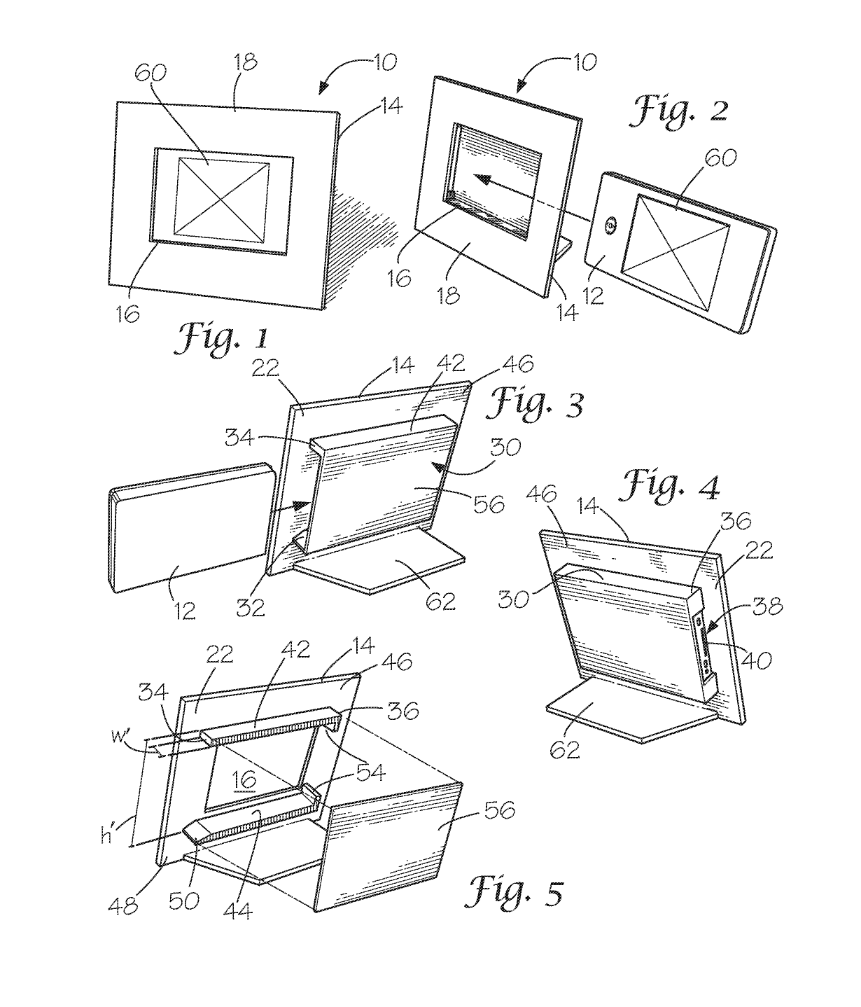

Referring now to the drawings, the present invention provides a frame 10 for receiving a portable electronic device 12. The structure of the frame 10 includes a frame body 14, usually having a square or rectangular shape that forms a border around a display opening 16 as shown in FIG. 1. The frame body 14 may be constructed of wood, plastic, metal or any suitable combination. The border formed by the frame body 14 includes a first surface 18. The first surface 18 faces outward to be viewed and provides a decorative appearance for the frame 10.

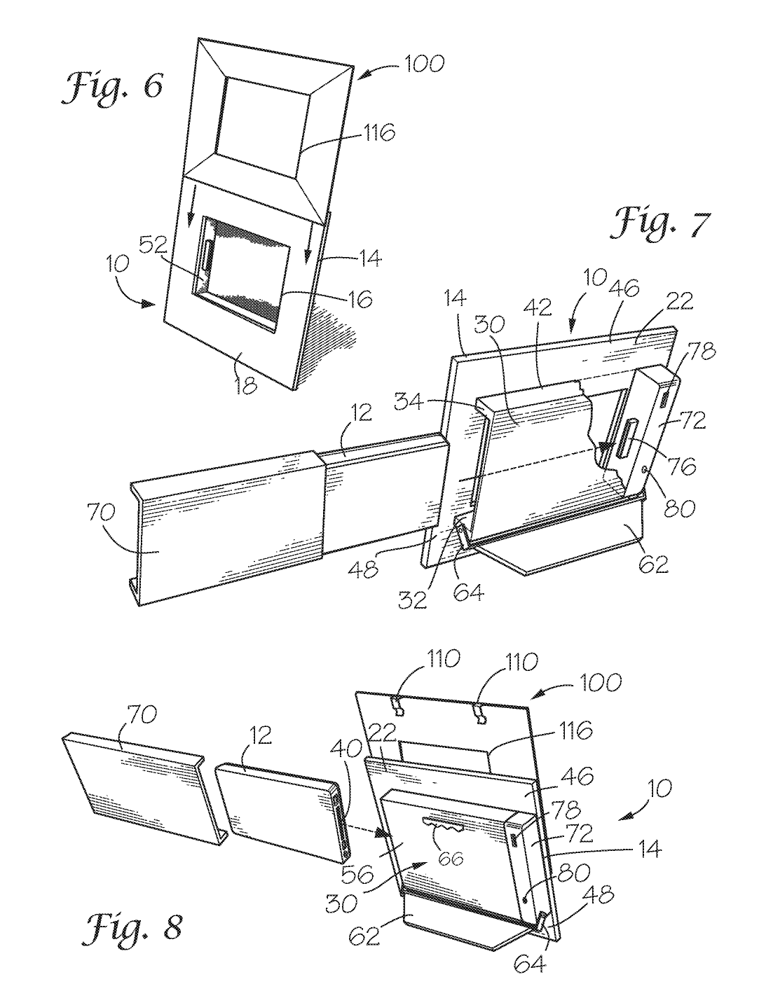

Alternatively, a separate front face member 100 as shown in FIG. 6 may be outwardly displayed on a first surface of the frame body for providing a pleasing appearance. The front face member 100 may be integrally formed with the first surface 18 of the frame body 14 or provided as a detachable front face member that attaches to the frame body and covers the first surface. In the exemplary embodiment of FIG. 8, the front face member 100 is attached to the frame body by clips 110 situated on the top back surface of the front face member. By these means, the first surface 18 functions to either provide or support an aesthetically pleasing appearance for the frame 10 resembling a standard picture frame, as illustrated by the shaped ornamental edging or molding 116. As the front face member 100 may be removable from the frame body 14, and the frame 10 may be aesthetically customized with a choice of styles for covering the first surface 18. The width of the border may be varied according to design preferences, and the ornamentation on the first surface 18 by the front face member 100 may be varied accordingly, such that the frame 10 may be varied according to the desired ornamental appearance and the end user audience.

On a second surface 22 of the frame body 14 facing inwardly and typically hidden from view, a receptacle 30 is arranged and affixed for receiving and holding the portable electronic device 12. The frame body 14 extends past the periphery of the receptacle 30 on all sides so that the receptacle is hidden from view when the frame 10 is viewed from the front. The receptacle 30 includes a receiving slot 32 on the receptacle for insertion of the portable electronic device 12. An exemplary receiving slot 32 is shown in FIGS. 3 and 7 on a first end 34 of the receptacle 30. The receiving slot 32 is of such dimensions and form to receive the preferred device. By way of example, a preferred receiving slot 32 may measure 9-12 mm w′ by 55-65 mm h′. Such receiving slot 32 may receive a portable electronic device 12, including a cellular phone such as an APPLE IPHONE or a portable multimedia device such as a handheld computer or tablet computer including a MICROSOFT ZUNE, APPLE IPOD TOUCH or APPLE IPAD. Software may be provided for the portable electronic device 12 selected to improve ease of use and performance when used with the frame 10. In an alternative arrangement, the receiving slot 32 could be arranged on the top edge of the receptacle 30 so that the portable electronic device 12 would be dropped downward through the slot and into the receptacle. Furthermore, the frame body 14 may be rotated to reposition the receiving slot 32. Thus, a receiving slot 32 on the end as shown in FIG. 3 may be rotated and re-oriented upward. In the model shown this would reorient the device from a landscape to portrait display. Some portable electronic devices 12 include motion and orientation sensing technology that will permit the photos displayed by the device to change from landscape display to portrait display automatically when the device is rotated.

The opposite end 36 of the receptacle 30 distal from the receiving slot 32 may comprise an accessory opening 38 as shown in FIG. 4 for plugging various accessories into the port(s) 40 of the portable electronic device 12. Thereby, the accessories already included with the device such as an electric charging means may be used to provide power or other functions. Besides charging the portable electronic device 12 while used as a photo exhibitor, the accessory opening 38 may allow peripherals such as audio speakers, memory cards, or on/off switch to be accessible and enhance the use of the frame 10 when combined with the portable electronic device.

Like the frame body 14 discussed above, the receptacle 30 is generally square or rectangular shaped in accordance with the desired model of portable electronic device 12 to be used with the frame 10. Moreover, the receptacle 30 may include an upper retaining member 42 and a lower retaining member 44 as in the particular embodiment shown in FIG. 5. The retaining members 42, 44 shown in FIG. 5 are the width w′ of the receiving slot 32 of FIG. 3, and the retaining members are separated apart at the receiving slot first end 34 by the height h′. In a rectangular configuration, the upper and lower retaining members 42, 44 are parallel and affixed to an upper portion 46 and lower portion 48 of the second surface 22 on the rear face of the frame body 14. One of the retaining members may include a tapered edge 50 as shown on the receiving slot first end 34 of the lower retaining member 44 in FIG. 5. The tapered edge 50 will help avoid damage to the portable electronic device 12 along with other features of the invention.

As the portable electronic device 12 is inserted into the receptacle 30, the retaining members 42, 44 support the device and hold it in place to vertically align the display screen 60 of the device with the display opening 16 of the frame body 14. After being completely inserted, the display screen 60 of the portable electronic device 12 is aligned horizontally with the display opening 16 by an end member 52 joining the retaining members 42, 44 opposite the receiving slot 32 and optionally closing that opposite and opposing end of the receptacle 30. Alternatively, the portable electronic device 12 may abut opposing flange members 54 extending toward one another as shown in FIG. 5. The opposing flange members 54 form the accessory opening 38 as discussed above. In the example of FIG. 1, the display opening 16 corresponds with the display screen 60 size of the portable electronic device 12. The design of the frame 10 may vary according to the design and model of the portable electronic device 12 chosen, or the frame may be provided an optional protective sleeve 70 designed to fit a portable electronic device to a generic display opening 16 and receptacle 30. An additional protective sleeve 70 insert of different size and design may be purchased according to the model of the portable electronic device 12.

A back panel 56 is attached to the retaining members 42, 44 and may provide additional support to retain a portable electronic device 12 within the receptacle 30. Such back panel 56 may be irremovable or removable. For instance the back panel 56 may be permanently glued to the surface of the retaining members 42, 44, or the retaining members may widened to include a longitudinal slot in each for receiving and retaining the back panel separate from the portable electronic device 12. The back panel 56, the retaining members 42, 44 and the second surface 22 of the frame body 14 may be lined with a protective material to prevent damage to the portable electronic device 12 when inserted. Such material may include felt or other natural or synthetic materials.

The frame 10 conceals the various portions of the portable electronic device 12 except for the graphic display screen 60 of the portable electronic device. The display screen 60 is exposed through the display opening 16 to display photos or video through the frame body 14 as shown in FIG. 1. The frame 10 provides for a neat and pleasing appearance for the display screen 60 of the portable electronic device 12 resembling a digital photo frame. The frame 10 also accentuates the digital display screen 60 of the portable electronic device 12. With this invention, the consumer will be able to utilize their portable electronic device 12 and the frame 10 to display digital images in a manner similar to a digital photo frame.

The frame 10 is provided a stand 62 attached to the second surface 22 (i.e. rear face) or the back panel 56 for supporting the frame in a display position. The stand 62 shown in FIGS. 3-4 and 7-8 will support the frame 10 on a table top or other flat surface. The stand 62 may comprise a member extended rearward about 60-90 degrees outward from the lower portion 48 of the frame body 14. The stand 62 may fold or remove for hanging the frame 10 on a wall surface. FIGS. 7-8 illustrate a pivotal attachment member 64 for folding and collapsing the stand 62 against the back panel 56. A sawtooth hanger 66 is attached to the back panel 56 or second surface 22 of the frame 10 as shown in FIG. 8. Usually just one sawtooth hanger 66 is placed at the center of the top rail of the frame body 14 or the center top portion of the back panel 56, with the serrated teeth of the hanger facing downward for hanging on the wall. Other, more secure, frame hanging methods may be incorporated into the frame body 14 or back panel 56 according to preference in lieu of the sawtooth hanger 66.

FIGS. 7-8 show the portable electronic device 12 being inserted into the receptacle 30 on the frame 10 in an additional embodiment. As shown, a protective sleeve 70 is provided to prevent scratches and other damage to the portable electronic device 12. Moreover, the protective sleeve 70 may also improve the fit of the portable electronic device 12 into the receptacle 30. In the embodiment shown, the portable electronic device 12 slides into the protective sleeve 70, and the protective sleeve covers the top, bottom and back of the device. The portable electronic device 12 and protective sleeve 70 slide into the receptacle 30 for alignment of the device display screen 60 with the display opening 16 of the frame 10. The protective sleeve 70 may include a liner to protect the portable electronic device 12 or a construction of soft material to improve the fit of the portable electronic device into the receptacle 30.

FIGS. 6-9 also show an electronic module 72 built into the receptacle 30 on the opposite end 36 opposing the receiving slot 32. The electronic module 72 plugs into the port 40 on the portable electronic device 12 and includes a connector 76 for insertion into the port. The connector 76 is shown in generic form and can be fashioned according to the port style on the selected portable electronic device 12. The electronic module 72 includes the necessary circuits and electronics to interface with the portable electronic device 12 and may provide means for charging the device and means for port replication.

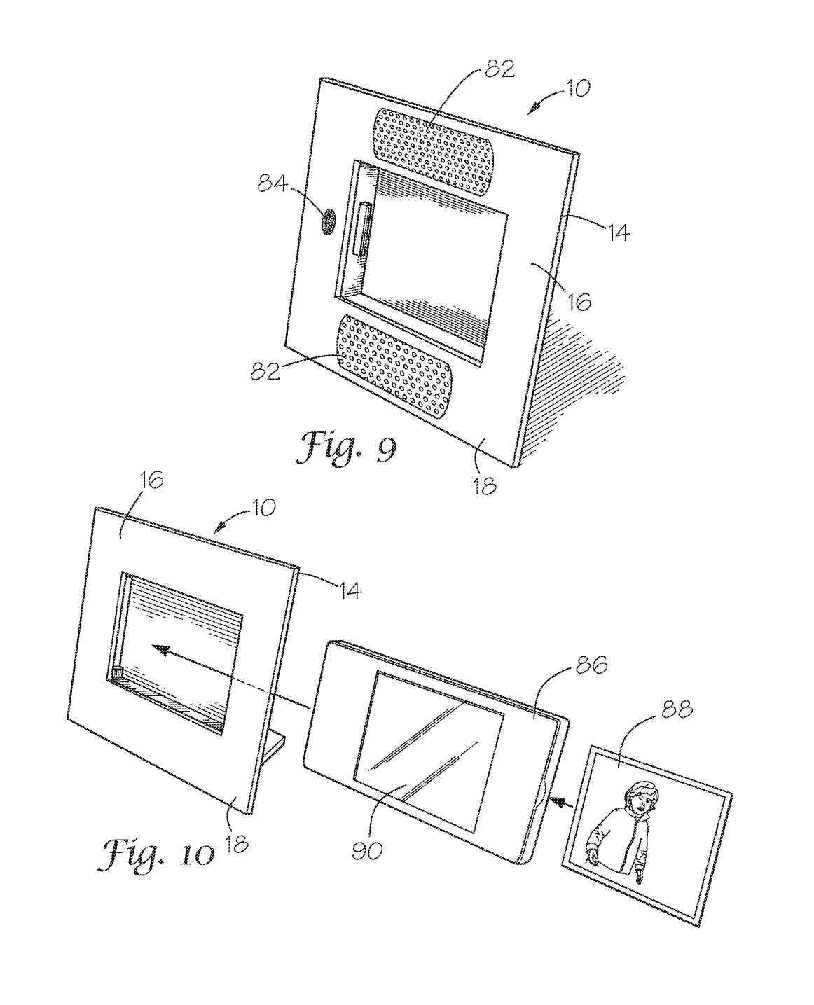

Exemplary ports are shown on the electronic module 72 including a connector 78 for power/charger and a connector 80 for external audio speakers. Note that the frame 10 may be used as a power charging dock without the portable electronic device being used to display photos. This provides additional flexibility for the end user. Additional ports may include a connector for synchronization cable, external memory storage transfer, or video, etc. As shown in FIG. 9, the electronic module 72 may operate to connect the device to integrate peripherals such as audio speakers 82 that are arranged within the frame body 14. Additionally, the electronic module 72 may connect the portable electronic device 12 to one or more control(s) 84 that are integrated into the frame body 14, such as the microphone or activation button shown on the first surface 18 of the frame body in FIG. 9. Such control 84 on the frame body 14 may simply consist of a cut-out in the frame body for exposing a pre-arranged control on the portable electronic device 12. The arrangement of controls integrated with the electronic module 72 provides a streamlined appearance for the digital display screen 60 of the portable electronic device 12 within the frame 10 while allowing operation of the device without removal of the device from the receptacle 30. For instance, the portable electronic device 12 that comprises a cellular phone could be used as a speaker phone while remaining within the receptacle 30 of the frame 10.

At times, the frame 10 will not contain the portable electronic device 12 while the device is removed. In those instances, it is desirable to avoid having an empty display opening 16 in the frame 10. A photo insert 86 is shown in FIG. 10 in which a printed photograph 88 is held by the photo insert or, alternatively, the aforementioned protective sleeve 70, which may also serve as a photo insert. When the portable electronic device 12 is removed from the frame 10, the photo insert 86 is utilized to fill the receptacle 30 and display the printed photo 88 in the display opening 16. The photo insert 86 may include a plastic or glass cover 90 within the insert and situated for covering the printed photo 88 to protect the photo and enhance the display within the frame 10. The photo insert 86 has about the same width and height as the receptacle 30 to fit the receptacle having width w′ and height h′ to replace the portable electronic device 12 when removed. When the photo insert 86 is used, the casual observer will not notice that the frame 10 is designed for holding a portable electronic device 12, as the frame will closely resemble a normal photo frame when viewed from the front.

While the invention has been described in terms of various specific embodiments, those skilled in the art will recognize that the invention can be practiced with modification within the spirit and scope of the claims.

1. A frame for a portable electronic device comprising a frame body having a first surface forming a decorative border of the frame and defining a display opening, the frame body having a second surface on opposite surface of the frame body from the first surface, a receptacle arranged with respect to the second surface for receiving the portable electronic device, the receptacle including a receiving slot for insertion of the portable electronic device, and the receptacle holding the portable electronic device for alignment of a display of the portable electronic device with the display opening of the frame.

2. A frame for a portable electronic device as in claim 1 in which the receptacle includes means for holding the portable electronic device for alignment of the display of the portable electronic device with the display opening of the frame while the display opening is centrally framed by the frame body.

3. A frame for a portable electronic device as in claim 1 including a protective sleeve that covers the portable electronic device, and the receptacle is configured to receive the protective sleeve and hold the portable electronic device with the display of the portable electronic device aligned for visual display through the display opening of the frame body.

4. A frame for a portable electronic device as in claim 1 including a removable printed photo insert that is sized in accordance with the size of a portable electronic device or inserted into a protective sleeve and received by the receptacle that visually displays a printed photo on the insert through the display opening of the frame body.

5. A frame for a portable electronic device as in claim 4 in which the printed photo insert includes a plastic or glass cover over the printed photo.

6. A frame for a portable electronic device as in claim 1 in which receptacle has a peripheral boundary and the frame body extends past the periphery of the receptacle, whereby the receptacle is hidden from view when the frame is viewed facing the first surface of the frame body.

7. A frame for a portable electronic device as in claim 1 in which the decorative border of the first surface is formed by a front face that is detachable from the first surface.

8. A frame for a portable electronic device as in claim 7 in which the front face is attached to the first surface by clips.

9. A frame for a portable electronic device as in claim 7 in which the front face is removable to change the decorative border or aesthetics of the frame.

10. A frame for a portable electronic device as in claim 1 in which the receptacle includes a pair of retaining members on opposing sides of the receptacle defining a space for supporting and vertically aligning the portable electronic device so that the display screen of the device is aligned with the display opening of the frame.

11. A frame for a portable electronic device as in claim 10 in which at least one of the retaining members on an end forming the receiving slot includes a tapered edge for widening the receiving slot.

12. A frame for portable electronic device as in claim 10 in which one end of the pair of retaining members on opposing sides of the receptacle defines the receiving slot and an opposite end of the retaining members include an end member or opposing flanges defining an opposite end of the receptacle from the receiving slot, whereby the portable display device is horizontally aligned within the receptacle for alignment of the device display with the frame's display opening.

13. A frame for a portable electronic device as in claim 1 in which the receptacle includes an accessory opening on an opposite end of the receptacle distal from the receiving slot.

14. A frame for a portable electronic device as in claim 1 in which the receptacle includes an electronic module for connection to the portable electronic device upon insertion of the device into the frame.

15. A frame for a portable electronic device as in claim 14 in which the electronic module includes means to control power to the portable electronic device.

16. A frame for a portable electronic device as in claim 14 in which the electronic module includes means for attachment of accessories to the portable electronic device including audio speakers external to the portable electronic device.

17. A frame for a portable electronic device as in claim 1 including a stand attached to the second surface of the frame body or to a back panel of the receptacle.
